(19) United States
(12) Patent Application Publication
(10) Pub. No.: US 2026/0047030 A1
(43) Pub. Date: Feb. 12, 2026

(54) FAST FABRIC RACK ARCHITECTURE FOR AI

(71) Applicant: Cisco Technology, Inc., San Jose, CA (US)

(72) Inventors: Edward Albert Warnicke, Austin, TX (US); Michael Sean McGee, Georgetown, TX (US); Kuppuswamy Sivakumar, Milpitas, CA (US); Tushar Umedbhai Patel, Sunnyvale, CA (US); Janine Joy Tinsley, San Jose, CA (US); Christopher David Liljenstolpe, San Francisco, CA (US)

(73) Assignee: Cisco Technology, Inc., San Jose, CA (US)

(21) Appl. No.: 19/288,479

(22) Filed: Aug. 1, 2025

Related U.S. Application Data
(60) Provisional application No. 63/680,485, filed on Aug. 7, 2024.

(51) Int. Cl. H05K 7/14

(52) U.S. Cl. CPC H05K 7/1492; H05K 7/1498

(57) ABSTRACT

In one implementation, a switch tray for a fabric rack includes internal connectors configured to communicatively couple the switch tray to processors located within the fabric rack via a cable backplane. The switch tray also includes a plurality of switch application-specific integrated circuits (ASICs) coupled to the internal connectors and configured to switch intra-rack traffic between the processors located within the fabric rack. The switch tray further includes external connectors coupled to the plurality of switch ASICs, whereby the plurality of switch ASICs are further configured to switch inter-rack traffic between the processors located within the fabric rack and external processors located in one or more external fabric racks.

### RELATED APPLICATION

This application claims priority to U.S. Prov. Appl. Ser. No. 63/680,485, filed Aug. 7, 2024, entitled “FAST FABRIC RACK ARCHITECTURE FOR AI” by Warnicke, et al., the contents of which are incorporated herein by reference.

### TECHNICAL FIELD

The present disclosure relates generally to computer networks and more particularly to a fast fabric rack architecture for artificial intelligence (AI).

### BACKGROUND

Recently, generative AI has exhibited a rapid increase in its capabilities and potential uses across a wide range of industries. For instance, large language models (LLMs) such as ChatGPT and the like are able to generate text regarding a wide array of topics. In more complex scenarios, LLM-based agents are able to generate code and interact with computer systems via application programming interfaces (APIs), allowing such agents to control an underlying system or process.

AI requires an ever-increasing amount of bandwidth between an ever-growing number of graphics processing units (GPUs). This has driven ‘rack level’ designs with a number of compute shelves connected to a number of switch shelves via a fixed cable backplane. Compute/Switch shelves mate with this backplane via fixed connectors. This enables a high bandwidth GPU to GPU ‘scale-up’ fabric within a given rack, but communications between racks fall back on much lower bandwidth ‘scale-out’ fabric using traditional network interface controllers (NICs). However, these NICs are not only slower by a factor of ten, but also more expensive and utilize more power.

### BRIEF DESCRIPTION OF THE DRAWINGS

The implementations herein may be better understood by referring to the following description in conjunction with the accompanying drawings in which like reference numerals indicate identically or functionally similar elements, of which:

FIG. 1 illustrates an example computer network;

FIG. 2 illustrates an example computing device/node;

FIG. 3 illustrates an example of interfacing with a generative model;

FIG. 4 illustrates an example architecture for a fast fabric rack;

FIG. 5 illustrates an example dual switch tray for a fast fabric rack;

FIGS. 6A-6E illustrate examples of the expansion of a pod to add graphics processing units (GPUS) using the dual switch tray of FIG. 5;

FIG. 7 illustrates an example of different communication planes between GPUs;

FIGS. 8A-8B illustrate an example of scaling up a fast fabric;

FIG. 9 illustrates an example of using packet spraying in a fast fabric; and

FIG. 10 illustrates an example simplified procedure for operating a switch tray of a fabric rack, in accordance with one or more implementations described herein.

### DESCRIPTION OF EXAMPLE IMPLEMENTATIONS

### Overview

According to one or more implementations of the disclosure, a switch tray for a fabric rack includes internal connectors configured to communicatively couple the switch tray to processors located within the fabric rack via a cable backplane. The switch tray also includes a plurality of switch application-specific integrated circuits (ASICs) coupled to the internal connectors and configured to switch intra-rack traffic between the processors located within the fabric rack. The switch tray further includes external connectors coupled to the plurality of switch ASICs, whereby the plurality of switch ASICs are further configured to switch inter-rack traffic between the processors located within the fabric rack and external processors located in one or more external fabric racks.

Other implementations are described below, and this overview is not meant to limit the scope of the present disclosure.

### DESCRIPTION

A computer network is a geographically distributed collection of nodes interconnected by communication links and segments for transporting data between end nodes, such as personal computers and workstations, or other devices, such as sensors, etc. Many types of networks are available, ranging from local area networks (LANs) to wide area networks (WANs). LANs typically connect the nodes over dedicated private communications links located in the same general physical location, such as a building or campus. WANs, on the other hand, typically connect geographically dispersed nodes over long-distance communications links, such as common carrier telephone lines, optical lightpaths, synchronous optical networks (SONET), synchronous digital hierarchy (SDH) links, and others. The Internet is an example of a WAN that connects disparate networks throughout the world, providing global communication between nodes on various networks. Other types of networks, such as field area networks (FANs), neighborhood area networks (NANs), personal area networks (PANs), enterprise networks, etc. may also make up the components of any given computer network. In addition, a Mobile Ad-Hoc Network (MANET) is a kind of wireless ad-hoc network, which is generally considered a self-configuring network of mobile routers (and associated hosts) connected by wireless links, the union of which forms an arbitrary topology.

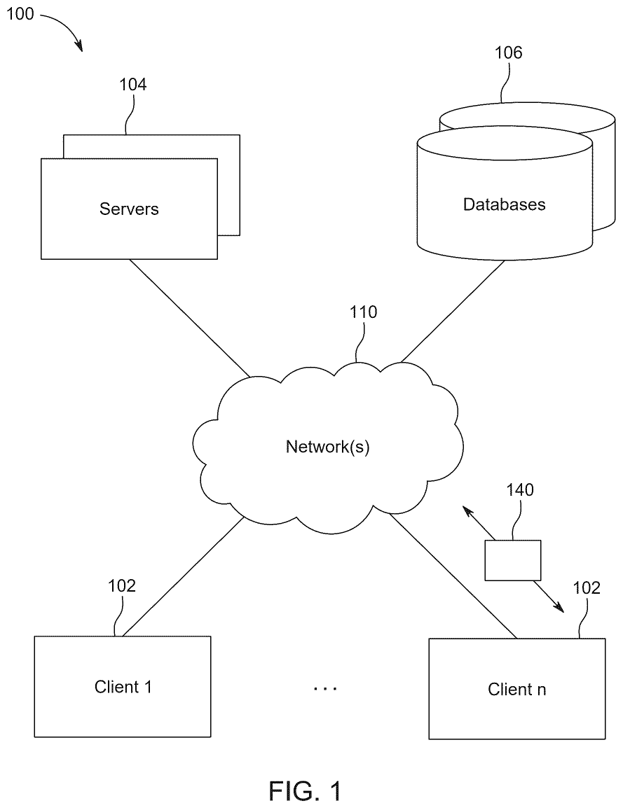

FIG. 1 is a schematic block diagram of an example simplified computing system (e.g., the computing system 100), which includes client devices 102 (e.g., a first through nth client device), one or more servers 104, and databases 106 (e.g., one or more databases), where the devices may be in communication with one another via any number of networks (e.g., network(s) 110). The network(s) 110 may include, as would be appreciated, any number of specialized networking devices such as routers, switches, access points, etc., interconnected via wired and/or wireless connections. For example, client devices 102, the one or more servers 104 and/or the intermediary devices in network(s) 110 may communicate wirelessly via links based on WiFi, cellular, infrared, radio, near-field communication, satellite, or the like. Other such connections may use hardwired links, e.g., Ethernet, fiber optic, etc. The nodes/devices typically communicate over the network by exchanging discrete frames or packets of data (packets 140) according to predefined protocols, such as the Transmission Control Protocol/Internet Protocol (TCP/IP) other suitable data structures, protocols, and/or signals. In this context, a protocol consists of a set of rules defining how the nodes interact with each other.

Client devices 102 may include any number of user devices or end point devices configured to interface with the techniques herein. For example, client devices 102 may include, but are not limited to, desktop computers, laptop computers, tablet devices, smart phones, wearable devices (e.g., heads up devices, smart watches, etc.), set-top devices, smart televisions, Internet of Things (IOT) devices, autonomous devices, or any other form of computing device capable of participating with other devices via network(s) 110.

Notably, in some implementations, the one or more servers 104 and/or databases 106, including any number of other suitable devices (e.g., firewalls, gateways, and so on) may be part of a cloud-based service. In such cases, the servers and/or databases 106 may represent the cloud-based device(s) that provide certain services described herein, and may be distributed, localized (e.g., on the premise of an enterprise, or “on prem”), or any combination of suitable configurations, as will be understood in the art.

Those skilled in the art will also understand that any number of nodes, devices, links, etc. may be used in computing system 100, and that the view shown herein is for simplicity. Also, those skilled in the art will further understand that while the network is shown in a certain orientation, the computing system 100 is merely an example illustration that is not meant to limit the disclosure.

Notably, web services can be used to provide communications between electronic and/or computing devices over a network, such as the Internet. A web site is an example of a type of web service. A web site is typically a set of related web pages that can be served from a web domain. A web site can be hosted on a web server. A publicly accessible web site can generally be accessed via a network, such as the Internet. The publicly accessible collection of web sites is generally referred to as the World Wide Web (WWW).

Also, cloud computing generally refers to the use of computing resources (e.g., hardware and software) that are delivered as a service over a network (e.g., typically, the Internet). Cloud computing includes using remote services to provide a user's data, software, and computation.

Moreover, distributed applications can generally be delivered using cloud computing techniques. For example, distributed applications can be provided using a cloud computing model, in which users are provided access to application software and databases over a network. The cloud providers generally manage the infrastructure and platforms (e.g., servers/appliances) on which the applications are executed. Various types of distributed applications can be provided as a cloud service or as a Software as a Service (SaaS) over a network, such as the Internet.

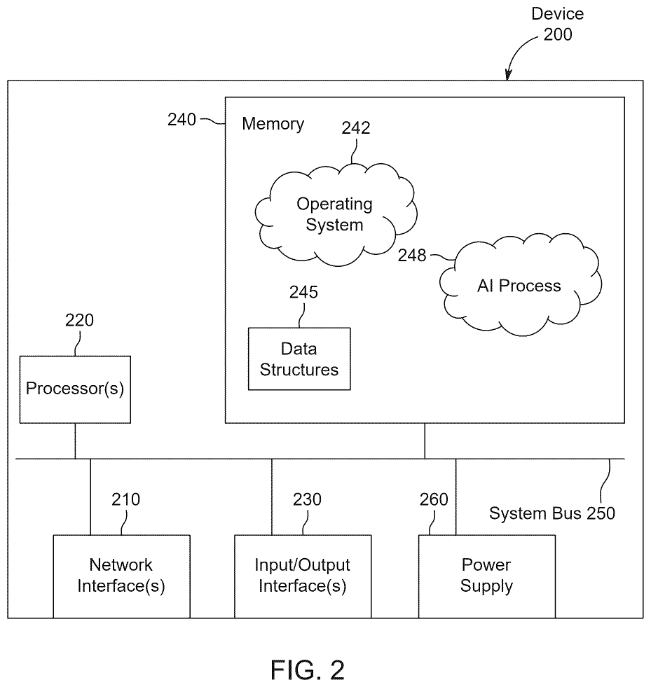

FIG. 2 is a schematic block diagram of an example node/device 200 (e.g., an apparatus) that may be used with one or more implementations described herein, e.g., as any of the devices shown in FIG. 1 above. Device 200 may comprise one or more network interfaces, such as interfaces 210 (e.g., wired, wireless, network interfaces, etc.), at least one processor (e.g., processor 220), and a memory 240 interconnected by a system bus 250, as well as a power supply 260 (e.g., battery, plug-in, etc.).

The interfaces 210 contain the mechanical, electrical, and signaling circuitry for communicating data over links coupled to the network(s) 110. The network interfaces may be configured to transmit and/or receive data using a variety of different communication protocols. Note, further, that device 200 may have multiple types of network connections via interfaces 210, e.g., wireless and wired/physical connections, and that the view herein is merely for illustration.

Depending on the type of device, other interfaces, such as input/output (I/O) interfaces 230, user interfaces (UIs), and so on, may also be present on the device. Input devices, in particular, may include an alpha-numeric keypad (e.g., a keyboard) for inputting alpha-numeric and other information, a pointing device (e.g., a mouse, a trackball, stylus, or cursor direction keys), a touchscreen, a microphone, a camera, and so on. Additionally, output devices may include speakers, printers, particular network interfaces, monitors, etc.

The memory 240 comprises a plurality of storage locations that are addressable by the processor 220 and the interfaces 210 for storing software programs and data structures associated with the implementations described herein. The processor 220 may comprise hardware elements or hardware logic adapted to execute the software programs and manipulate the data structures 245. An operating system 242, portions of which are typically resident in memory 240 and executed by the processor, functionally organizes the device by, among other things, invoking operations in support of software processes and/or services executing on the device. These software processes and/or services may comprise AI process 248, as described herein. In further implementations, memory 240 may be, or include, an external memory connected to device 200 via a connector (e.g., USB, etc.) and/or network.

It will be apparent to those skilled in the art that other processor and memory types, including various computer-readable media, may be used to store and execute program instructions pertaining to the techniques described herein. Also, while the description illustrates various processes, it is expressly contemplated that various processes may be implemented as modules configured to operate in accordance with the techniques herein (e.g., according to the functionality of a similar process). Further, while processes may be shown and/or described separately, those skilled in the art will appreciate that processes may be routines or modules within other processes.

In various implementations, as detailed further below, AI process 248 may include computer executable instructions that, when executed by processor 220, cause device 200 to perform the techniques described herein. To do so, in some implementations, AI process 248 may utilize and/or be a component of machine learning implementations. In general, machine learning is concerned with the design and the development of techniques that take as input empirical data (such as network statistics and performance indicators) and recognize complex patterns in these data. One very common pattern among machine learning techniques is the use of an underlying model M, whose parameters are optimized for minimizing the cost function associated to M, given the input data. For instance, in the context of classification, the model M may be a straight line that separates the data into two classes (e.g., labels) such that M=a*x+b*y+c and the cost function would be the number of misclassified points. The learning process then operates by adjusting the parameters a, b, c such that the number of misclassified points is minimal. After this optimization phase (or learning phase), the model M can be used very easily to classify new data points. Often, M is a statistical model, and the cost function is inversely proportional to the likelihood of M, given the input data.

In various implementations, AI process 248 may employ and/or be utilized to handle prompts to and/or access of one or more supervised, unsupervised, or semi-supervised machine learning models. Generally, supervised learning entails the use of a training set of data that is used to train the model to apply labels to the input data. For example, the training data may include sample configurations labeled with textual metadata. On the other end of the spectrum are unsupervised techniques that do not require a training set of labels. Notably, while a supervised learning model may look for previously seen patterns that have been labeled as such, an unsupervised model may instead look to whether there are sudden changes or patterns in the behavior of the metrics. Semi-supervised learning models take a middle ground approach that uses a greatly reduced set of labeled training data.

Example machine learning techniques that AI process 248 can employ and/or be utilized in concert with may include, but are not limited to, nearest neighbor (NN) techniques (e.g., k-NN models, replicator NN models, etc.), statistical techniques (e.g., Bayesian networks, etc.), clustering techniques (e.g., k-means, mean-shift, etc.), neural networks (e.g., reservoir networks, artificial neural networks, etc.), support vector machines (SVMs), generative adversarial networks (GANs), long short-term memory (LSTM), logistic or other regression, Markov models or chains, principal component analysis (PCA) (e.g., for linear models), singular value decomposition (SVD), multi-layer perceptron (MLP) artificial neural networks (ANNs) (e.g., for non-linear models), replicating reservoir networks (e.g., for non-linear models, typically for timeseries), random forest classification, or the like.

In further implementations, AI process 248 may also include, or otherwise use or be employed to operate with, one or more generative artificial intelligence/machine learning models. In contrast to discriminative models that simply seek to perform pattern matching for purposes such as anomaly detection, classification, or the like, generative approaches instead seek to generate new content or other data (e.g., audio, video/images, text, etc.), based on an existing body of training data. For instance, in the context of machine unlearning, AI process 248 may be a component of, use, and/or be utilized in the management of prompts/access to a generative model to perform layer attribution, perform layer sensitivity assessment, remove capabilities from a previously trained model, retain model performance, etc. based on a conversational input from a user (e.g., voice, text, etc.). Example generative approaches can include, but are not limited to, generative adversarial networks (GANs), large language models (LLMs), other transformer models, and the like.

The performance of a machine learning model can be evaluated in a number of ways based on the number of true positives, false positives, true negatives, and/or false negatives of the model. For example, consider the case of a model that predicts whether the QoS of a path will satisfy the service level agreement (SLA) of the traffic on that path. In such a case, the false positives of the model may refer to the number of times the model incorrectly predicted that the QoS of a particular network path will not satisfy the SLA of the traffic on that path. Conversely, the false negatives of the model may refer to the number of times the model incorrectly predicted that the QoS of the path would be acceptable. True negatives and positives may refer to the number of times the model correctly predicted acceptable path performance or an SLA violation, respectively. Related to these measurements are the concepts of recall and precision. Generally, recall refers to the ratio of true positives to the sum of true positives and false negatives, which quantifies the sensitivity of the model. Similarly, precision refers to the ratio of true positives to the sum of true and false positives.

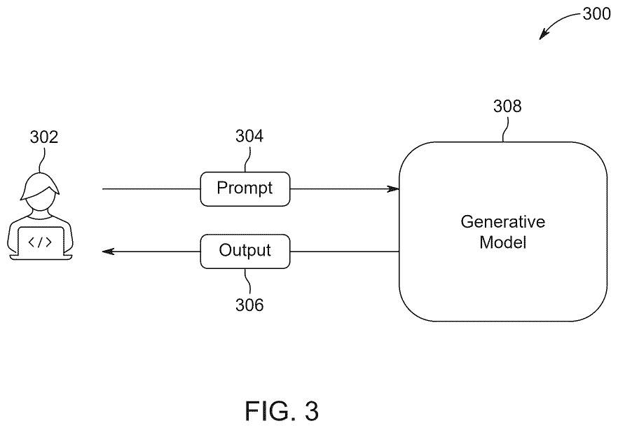

FIG. 3 illustrates an example 300 for interfacing with a language model, in various implementations. In example 300, a user 302 may send a prompt 304 (e.g., a query, a query augmented with additional data, documents, and/or images, etc.) to a generative model 308. The generative model 308 may be configured to process a prompt 304 to generate an output 306 to satisfy the prompt 304.

The generative model 308 may be a model configured to apply its trained algorithms to generate a response (e.g., output 306) based on the prompt 304 provided. For instance, in some cases, generative model 308 may take the form of a large language model (LLM), diffusion-based model, combinations thereof, or the like.

The output 306 may be the result produced by the generative model 308 (e.g., by the application of the generative model 308 to the prompt 304). This output can vary depending on the model's configuration and the task at hand. For example, the output 306 may include one or more of a generated and/or synthesized image, a text response, a classification and/or prediction, etc.

As noted above, AI requires an ever-increasing amount of bandwidth between an ever-growing number of graphics processing units (GPUs). This has driven ‘rack level’ designs with a number of compute shelves connected to a number of switch shelves via a fixed cable backplane.

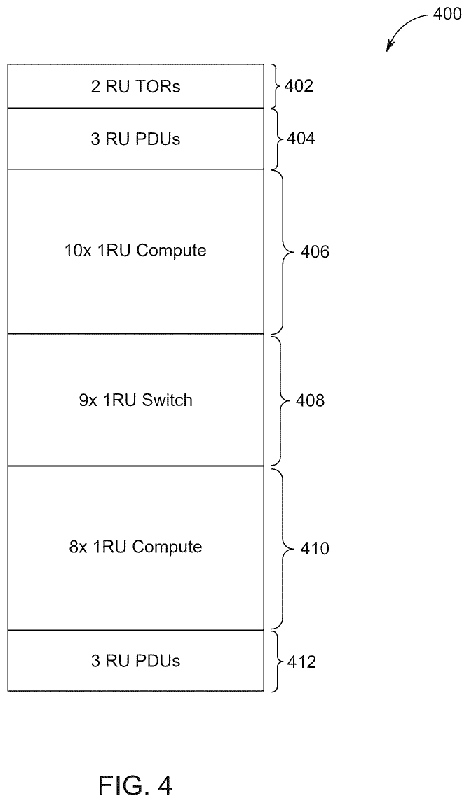

By way of illustration, FIG. 4 shows an example architecture for a fast fabric rack 400. As shown, fast fabric rack 400 may comprise a plurality of rack units (RUs), also referred to as “pods,” each of which has a dedicated function. For instance, fast fabric rack 400 may have a plurality of top of rack (TOR) RUs 402, a plurality of power distribution unit (PDU) RUs 404, a plurality of compute RUs 406, a plurality of switch RUs 408, a plurality of compute RUs 410, and a plurality of PDU RUs 412.

TOR RUs 402 may take the form of network switches that perform the functions of, e.g., connecting fast fabric rack 400 to a larger network within a data center.

PDU RUs 404 and PDU RUs 412 may be responsible for providing electrical power to the components of fast fabric rack 400.

Compute RUs 406 and compute RUs 410 may be responsible for providing the compute resources (e.g., for the AI application). For instance, compute RUs 406 and compute RUs 410 may include compute trays that each have four graphics processing units (GPUs). For instance, the GB200 NLV72 rack by NVIDIA Corporation has a total of 72 GPUs across a total of eighteen compute trays split up into a first group of ten trays and a second group of eight trays.

Switch RUs 408 may be responsible for providing high bandwidth switching between the racks/pods of fast fabric rack 400 as part of a switched fabric. This scale-up fabric allows the GPUs of compute RUs 406 and compute RUs 410 to communicate with one another, thereby allowing them to effectively act as a singular GPU for purposes of executing the AI application.

More specifically, the compute and switch trays of fast fabric rack 400 may mate with a backplane of fast fabric rack 400 via fixed connectors. This allows for the formation of a high bandwidth (e.g., 7.2 Tbps/GPU), GPU-to-GPU ‘scale-up’ fabric within a given rack, such as fast fabric rack 400, but communications between racks fall back on much a lower bandwidth, ‘scale-out’ fabric using traditional network interface controllers (NICs) per GPU connected to each GPU via PCIex16 or InfinityFabric. These NICs are approximately nine times slower than that of the scale-up fabric, as well as more expensive and utilize more power

A key challenge is that many compute racks/pods today only support a fixed number of GPUs. For instance, the NVL72 has a fixed pod size of seventy-two GPUs. This means that the customer is forced into a deployment of this size without consideration for their needs. Indeed, the compute/switch trays used in an NVL72 cannot be used in a smaller (or larger) system. This means that a customer cannot simply purchase a smaller system and grow. In addition, these types of racks also have relatively large power requirements, often requiring 120 KW per rack. Most datacenters are not equipped to deliver that much power density, thereby requiring new power delivery systems, as well.

### Fast Fabric Rack Architecture for AI

The techniques herein introduce a rack-based GPU architecture that allows an operator to flexibly choose greater scale-up bandwidth at lower cost and energy utilization than current architectures.

Illustratively, the techniques described herein may be performed by hardware, software, and/or firmware, such as in accordance with AI process 248, which may include computer executable instructions executed by the processor 220 (or independent processor of interfaces 210) to perform functions relating to the techniques described herein.

Specifically, according to various implementations, a switch tray for a fabric rack includes internal connectors configured to communicatively couple the switch tray to processors located within the fabric rack via a cable backplane. The switch tray also includes a plurality of switch application-specific integrated circuits (ASICs) coupled to the internal connectors and configured to switch intra-rack traffic between the processors located within the fabric rack. The switch tray further includes external connectors coupled to the plurality of switch ASICs, whereby the plurality of switch ASICs are further configured to switch inter-rack traffic between the processors located within the fabric rack and external processors located in one or more external fabric racks.

Operationally, a key observation herein is that switch trays/RUs in fast fabrics today typically utilize a single switch Application Specific Integrated Circuit (ASIC) with all of its ports occupied by connections to GPUs in the same pod/rack via the cable backplane. This type of configuration is generally referred to herein as a ‘single switch tray.’ While the single switch tray configuration allows for high bandwidth intra-pod communications between GPUs within a single pod (e.g., a single rack), inter-pod communications are still subject to lower bandwidths (e.g., ˜nine times lower) by using traditional NICs. This configuration is also inflexible with respect to the number of GPUs per pod (e.g., requiring a fixed set of 72 GPUs per pod).

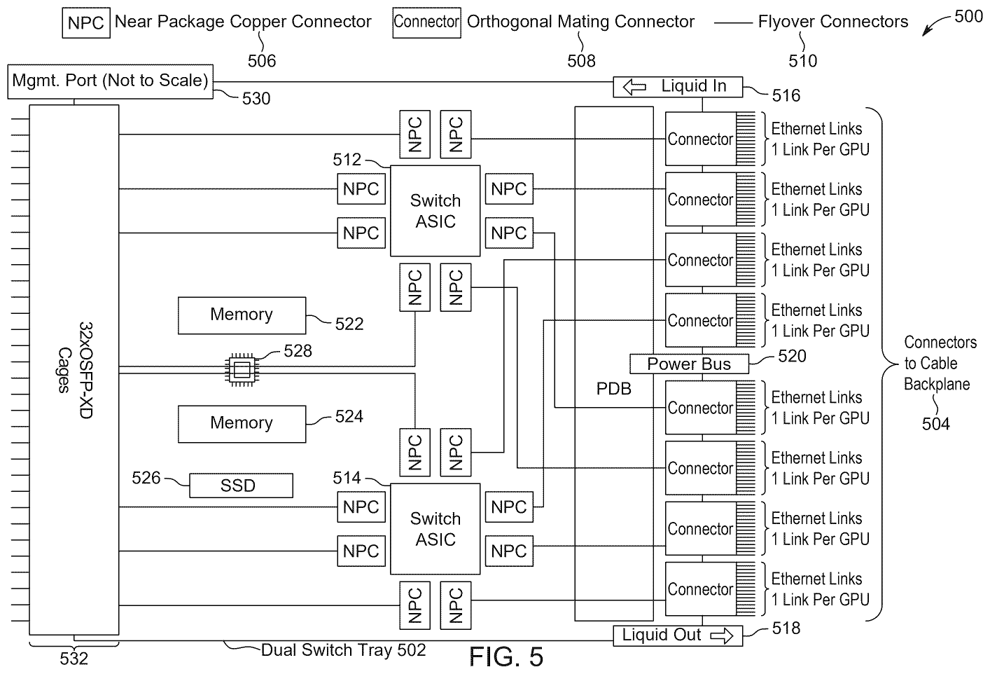

According to various implementations, the techniques herein introduce a ‘dual switch tray’ in which a portion of the ports of its switch ASIC(s) is wired for intra-pod communications between GPUs and the remaining portion of the ports wired to support inter-pod communications. By way of example, FIG. 5 illustrates an architecture 500 for a dual switch tray 502 for a fast fabric rack, according to some implementations.

As shown, dual switch tray 502 may include a plurality of switch ASICs, such as switch ASIC 512 and switch ASIC 514, and powered by a power bus 520 (e.g., a power distribution bus (PDB)). Each switch ASIC may have a plurality of ports connected to a plurality of GPUs within the pod in which dual switch tray 502 is installed. In addition, dual switch tray 502 may include connectors 504 to a cable backplane of the pod that comprises links to the GPUs of the pods. For instance, connectors 504 may be coupled to Ethernet links, with one link per GPU, and comprise orthogonal mating connectors 508. To interconnect the GPUs within the pod, each of switch ASIC 512 and switch ASIC 514 may have connectors 506, such as copper near package connectors (NPCs), connected to orthogonal mating connectors 508 via flyover connectors 510.

In some implementations, dual switch tray 502 may also be liquid cooled by inputting cool liquid via an inlet 516 and expelling the liquid via an outlet 518. Doing so allows for heat to be dissipated away from the components of dual switch tray 502 powered by power bus 520 such as switch ASIC 512, switch ASIC 514, memory 522, memory 524, solid state device (SSD) 526, processor 528, management port 530, or the like.

As would be appreciated, a single tray configuration may include a singular switch ASIC connected solely to connectors 504 to support intra-pod communications between the GPUs of the pod. In contrast, either or both of switch ASIC 512 and switch ASIC 514 may dedicate at least a portion of their ports to support intra-pod communications to allow the GPUs of the pod to communicate externally (e.g., with GPUs of other pods). For instance, half of the ports/NPCs of each of switch ASIC 512 and switch ASIC 514 may be connected within dual switch tray 502 to external connectors 532. For instance, external connectors 532 may take the form of thirty-two Octal Small Form Factor Pluggable-Extended Density (OSFP-XD) cages to connect the GPUs of the pod externally (e.g., using Ethernet). In further implementations, these front-of-tray, inter-pod connections could be high density optical module ports, near package optics, or any other mechanism allowing high radix connections over moderate distances.

Said differently, dual switch tray 502 represents an evolution from a switch tray containing one or more switching ASICs with all of their ports occupied by connections to GPUs in the same pod/rack via the cable backplane to a switch tray containing twice as many switching ASICs with each switching ASIC having half of their ports occupied by connections to GPUs in the same pod (i.e., intra-pod connections) via the cable backplane and the other half of the ports on each switching ASIC connected to a flexible mechanism via the front of the switch tray towards spine switches thus supporting inter-pod connectivity.

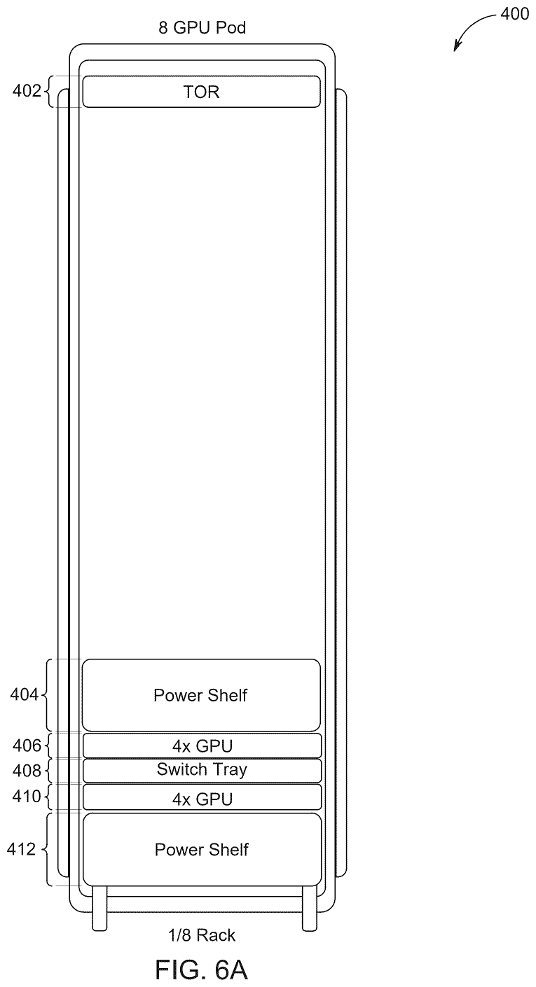

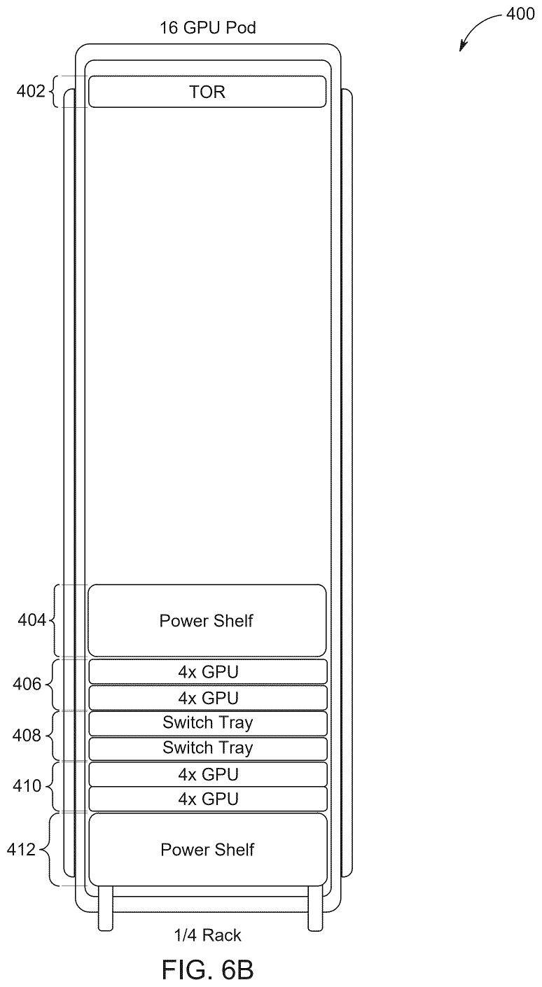

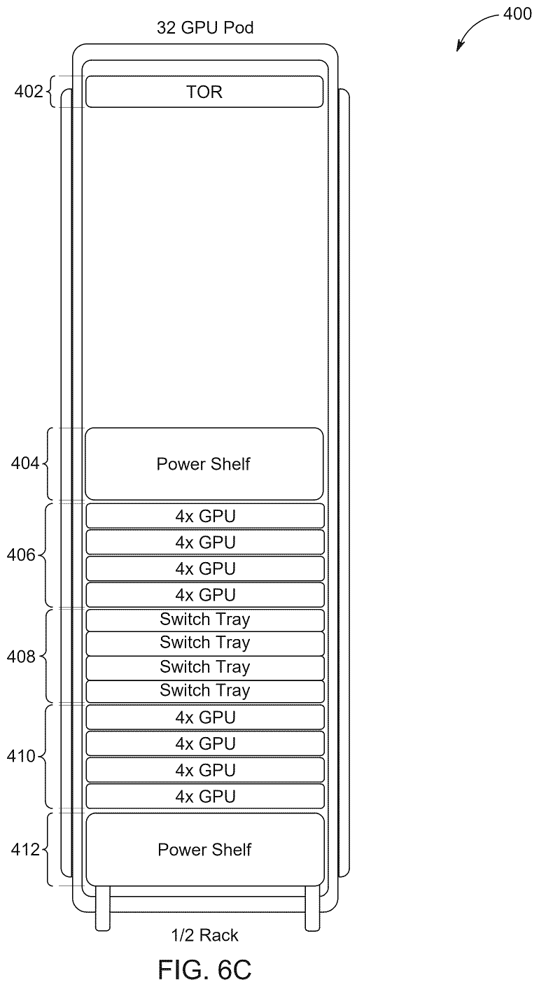

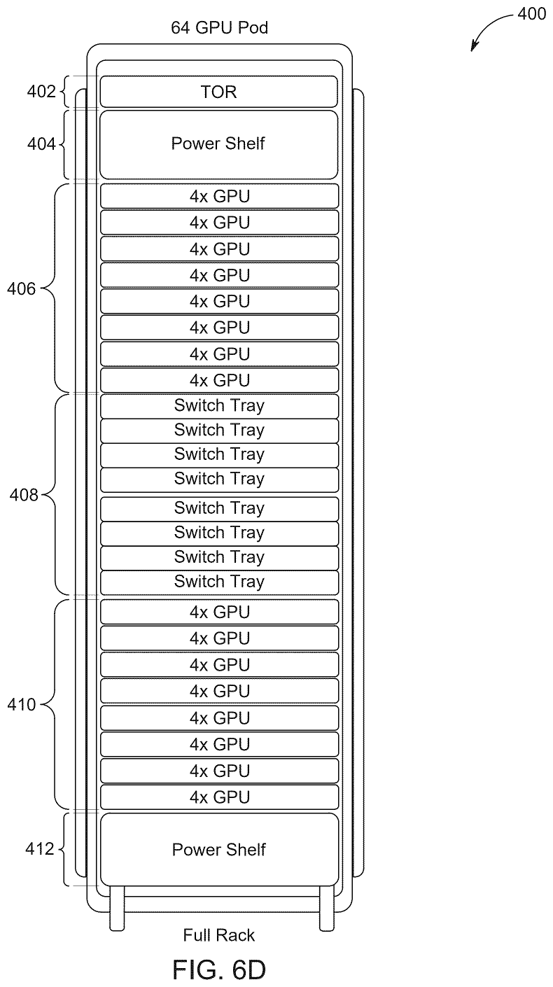

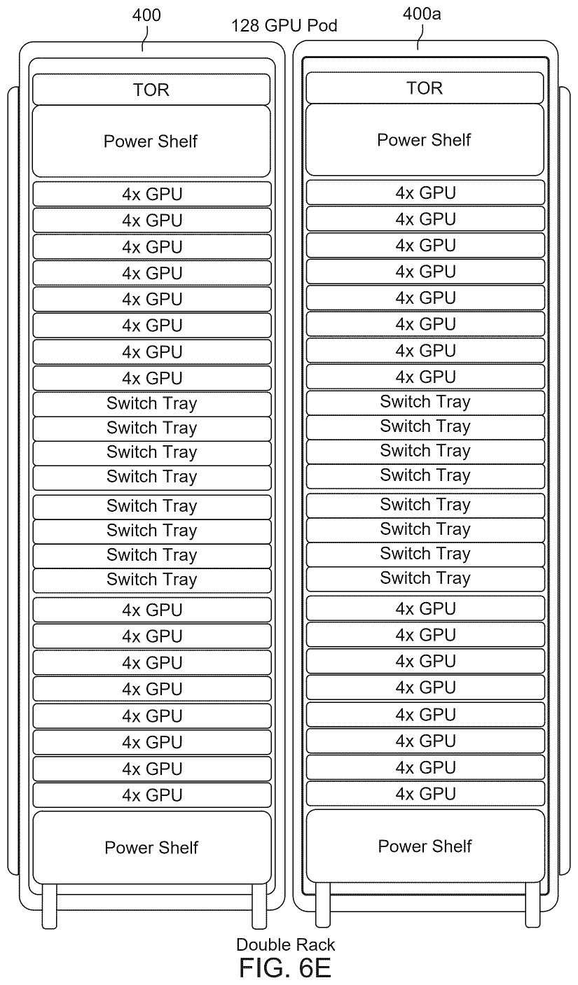

FIGS. 6A-6E illustrate examples of the expansion of a pod to add graphics processing units (GPUs) using the dual switch tray 502 of FIG. 5, according to various implementations. Continuing the example of FIG. 4, consider again fast fabric rack 400. In each switch slot of the plurality of switch RUs 408 of fast fabric rack 400, the operator may install either a single switch tray or dual switch tray 502, as desired. Both the single and dual switch tray provide a portion of the intra-pod scale-up fabric between the GPUs in the pod, such as those in compute RUs 406 and compute RUs 410. If a dual switch tray is used, then that fraction of the scale-up fabric bandwidth is also available for inter-pod scale-up via spine switches, as detailed below.

Since dual switch tray 502 is backwards compatible with existing deployment, the operator may also elect to substitute any number of single switch trays within fast fabric rack 400 with dual switch trays, such as dual switch tray 502, depending on their perception of their needs for inter-pod scale-up bandwidth.

Advantageously, the dual switch tray architecture introduced herein also allows the operator to start with a smaller amount of inter-pod scale-up bandwidth and increase it as they grow their cluster. This can be done by replacing single switch trays in existing pods with dual switch trays. The operator can then reuse those single switch trays in new pods being added to the cluster.

As shown in FIGS. 6A-6E, the ability to expand the scale-up fabric using inter-pod scale up also means that the operator can start with a smaller pod size and increase to a larger number of GPUs on their scale-up fabric over time. For instance, in FIG. 6A, the operator may begin with eight GPUs in fast fabric rack 400 using only one switch tray. To later increase the number of GPUs to sixteen, they may do so by increasing the number of switch trays to two, as shown in FIG. 6B. In FIG. 6C, then increasing the number of switch trays to four allows for a total of thirty-six GPUs within fast fabric rack 400. Doubling this to eight switch trays, as shown in FIG. 6D, then allows for the use of sixty-four GPUs. In some implementations, the pod can be further expanded by adding a second fast fabric rack 400a to fast fabric rack 400 to form a double rack pod that supports one hundred and twenty-eight GPUs. This expandability also allows an operator to size their pods according to their existing power infrastructure and later migrate their compute/switch trays to larger racks with larger cable backplanes as their capacity for higher power density grows.

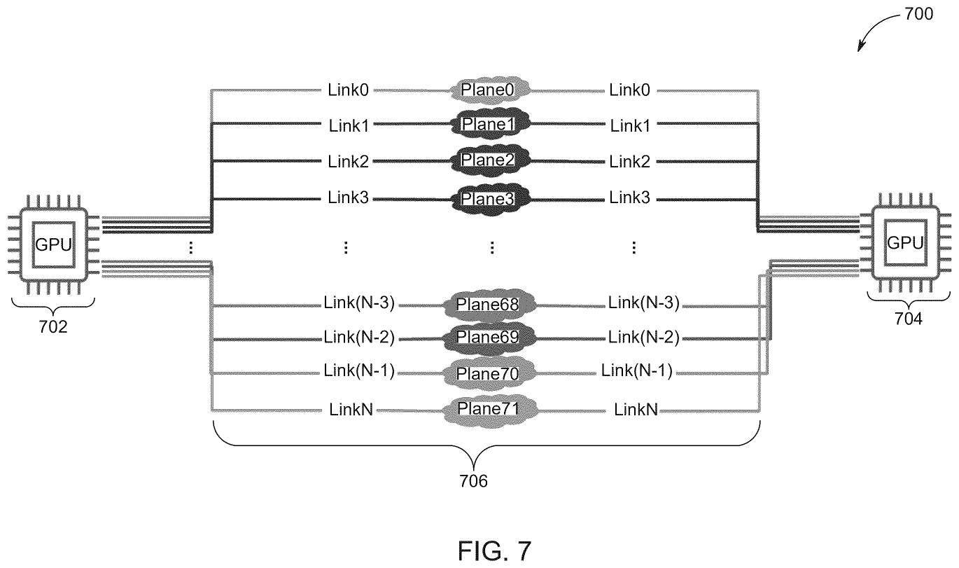

FIG. 7 illustrates an example 700 of different communication planes between GPUs, according to various implementations. As shown, packets sent out on a given link (e.g., LinkN) of a GPU are always addressed to that link of another GPU. Each networking ‘PlaneN’ needs to be able to switch amongst all of the GPUs attached to it by LinkN, but not to some different LinkM (LinkMs will all be attached to PlaneM for switching). For instance, GPU 702 may be connected to GPU 704 via planes 706, such as plane 71 associated with LinkN. The aggregate bandwidth of communication between any two GPUs attached to the same Scale-up Fabric will be (Link Speed)*(Number of Links).

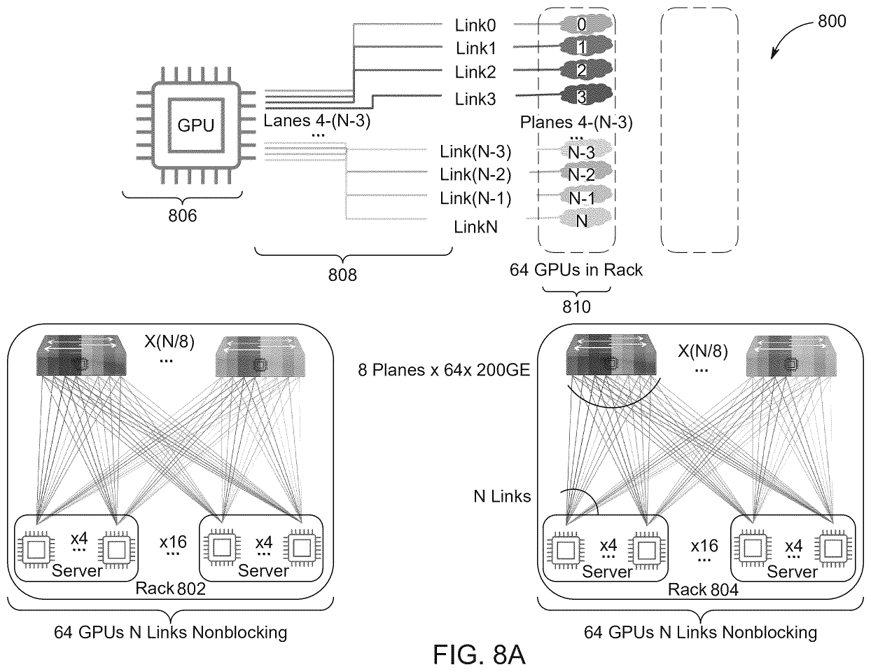

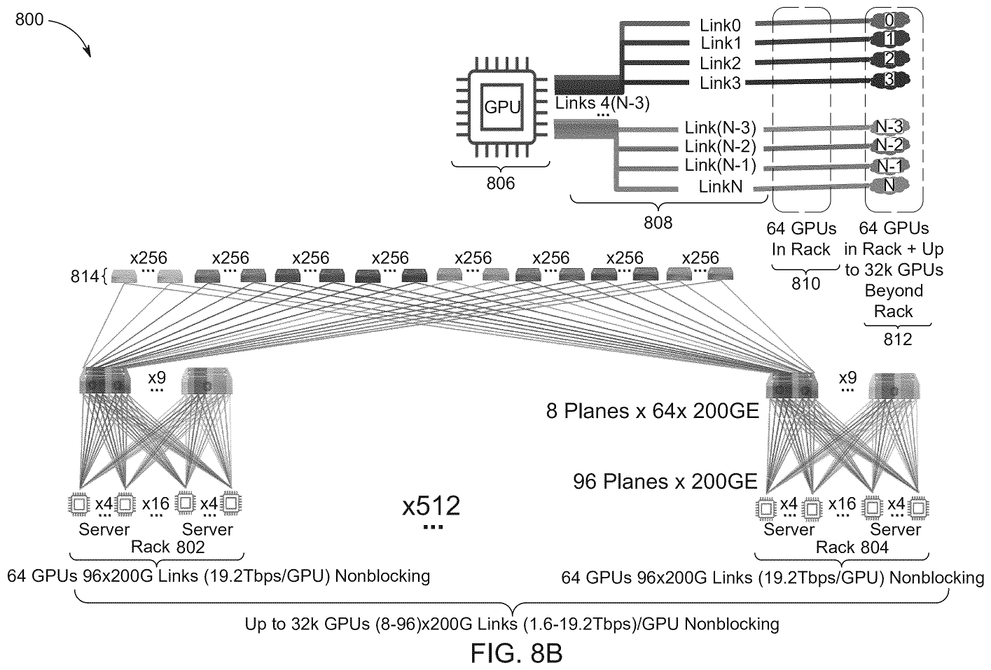

This concept of communication planes can also extend to inter-pod communications. For instance, FIGS. 8A-8B illustrate an example of scaling up a fast fabric, in various implementations. As shown in example 800 in FIG. 8A, consider the case in which there are two pods: a first pod/rack 802 and a second pod/rack 804. Within each may be sixty-four GPUs with N-number of non-blocking links. More specifically, a given GPU 806 may have N-number of planes 808 corresponding to its N-number of links to the other GPUs 810 within its rack/pod.

As shown in FIG. 8B, spine switches 814 may extend these planes to support inter-rack/pod communications between GPUs. Here, use of the dual switch tray architecture herein allows for planes 808 to connect given GPU 806 to not just GPUs 810 within its rack/pod, but a set of GPUs 812 that comprises both those local GPUs and a set of GPUs outside of that rack/pod (e.g., up to 32,000 GPUs in the configuration shown).

In other words, spine switches 814 may extend the internal communication planes within a given rack/pod, such as rack 802 and rack 804, to GPUs located in other racks/pods. In one implementation, each of spine switches 814 may be dedicated to a different communication plane. For instance, as shown, consider the case in which there are five hundred and twelve racks. In such a case, there may be up to 32,000 GPUs and (8-96)×200 G nonblocking links (1.6-19.2 Tbps) per GPU. Indeed, Infinity Fabric (IF) has a limit of 1024 IF addresses, so the Ethernet fabric may be segmented into ‘SuperPods’ of no more than 1024 GPUs.

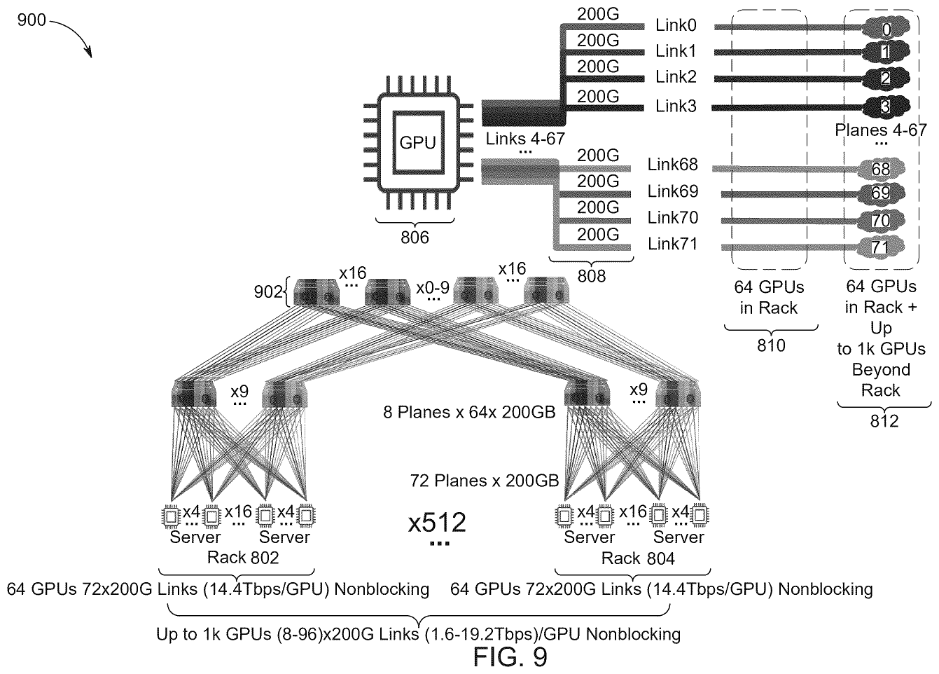

As would be appreciated, different configurations are also possible by leveraging the dual tray architecture introduced herein. For instance, FIG. 9 illustrates an example 900 of using packet spraying in a fast fabric, such as the one shown in FIGS. 8A-8B. Here, the idea is that rather than using flow-based Equal Cost MultiPath (ECMP) to select paths from leaf to spine 902, which could result in congestion due to elephant flows, the fabric could use packet spraying to spray packets evenly across all leaf-to-spine links. Packets will arrive out of order at the destination GPU, but the order of arrival is compensated for by receiving GPU/Infinity Fabric Protocol.

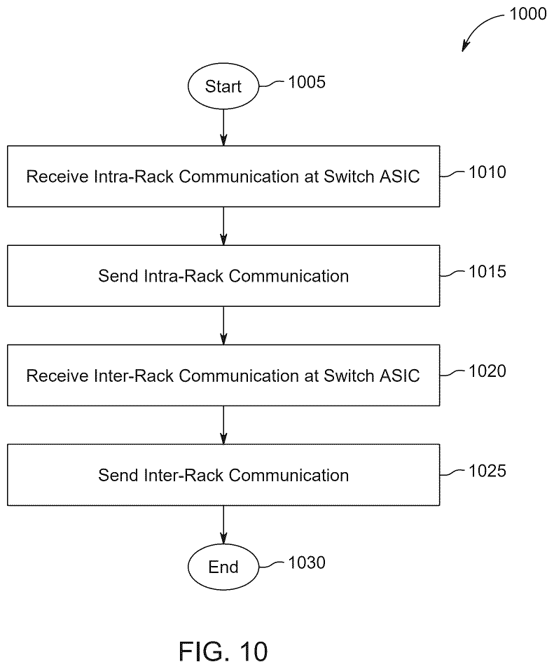

FIG. 10 illustrates an example simplified procedure 1000 for operating a switch tray of a fabric rack, in accordance with one or more implementations described herein. Procedure 1000 may start at step 1005 and continue on to step 1010 where, as described in greater detail, a switch ASIC of the switch tray may receive an intra-rack communication from a first processor located within the fabric rack and destined for a second processor located within the fabric rack.

At step 1015, as detailed above, the switch ASIC of the switch tray may send the intra-rack communication to the second processor located within the fabric rack.

At step 1020, the switch ASIC may receive an inter-rack communication from the first processor and destined for an external processor located external to the fabric rack, as described in greater detail above.

At step 1025, as detailed above, the switch ASIC may send the inter-rack communication via an external connector of the switch tray towards the external processor.

Procedure 1000 may then end at step 1030.

It should be noted that while certain steps within procedure 1000 may be optional as described above, the steps shown in FIG. 10 are merely examples for illustration, and certain other steps may be included or excluded as desired. Further, while a particular order of the steps is shown, this ordering is merely illustrative, and any suitable arrangement of the steps may be utilized without departing from the scope of the implementations herein.

While there have been shown and described illustrative implementations that provide for fast fabric rack architecture for artificial intelligence (AI), it is to be understood that various other adaptations and modifications may be made within the intent and scope of the implementations herein. In addition, while certain processes are shown, other suitable processes may be used, accordingly.

By allowing the operator to optionally replace a ‘Switch Tray’ with a ‘Dual Switch Tray’ with two 51.2 T Switch ASICs and 32 OSFP-XD-1600 cages in the front, this architecture enables the operator to choose ‘scale-up’ bandwidths of 800 G, 1.6 T, 2.4 T, 3.2 T, 4 T, or 4.8 T as they deem necessary by simply replacing a single switch tray with a dual switch tray. In addition, this allows the simplification of the Compute Shelf by removing the SuperNICs and PCIe Switches. Since the SuperNICs and PCIeSwitches are both more expensive and consume much more power than the switch ports that are replacing them, this enables the rack-based architecture to be both much cheaper and much lower power. Simple calculations show that this approach enables removing ˜$150 and costs and ˜7.5 kW of power consumption while increasing scale up bandwidth from 400 G to 800 G (for the 800 G single ‘Dual Switch Tray’ option) compared to the naive architecture.

The foregoing description has been directed to specific implementations. It will be apparent, however, that other variations and modifications may be made to the described implementations, with the attainment of some or all of their advantages. For instance, it is expressly contemplated that the components and/or elements described herein can be implemented as software being stored on a tangible (non-transitory) computer-readable medium (e.g., disks/CDs/RAM/EEPROM/etc.) having program instructions executing on a computer, hardware, firmware, or a combination thereof. Accordingly, this description is to be taken only by way of example and not to otherwise limit the scope of the implementations herein. Therefore, it is the object of the appended claims to cover all such variations and modifications as come within the true spirit and scope of the implementations herein.

1. A switch tray for a fabric rack comprising:
internal connectors configured to communicatively couple the switch tray to processors located within the fabric rack via a cable backplane;
a plurality of switch application-specific integrated circuits (ASICs) coupled to the internal connectors and configured to switch intra-rack traffic between the processors located within the fabric rack; and
external connectors coupled to the plurality of switch ASICs, wherein the plurality of switch ASICs are further configured to switch inter-rack traffic between the processors located within the fabric rack and external processors located in one or more external fabric racks.

2. The switch tray as in claim 1, wherein the processors located within the fabric rack are graphics processing units (GPUs).

3. The switch tray as in claim 1, wherein the fabric rack comprises one or more compute trays that are coupled to the cable backplane and house the processors located within the fabric rack.

4. The switch tray as in claim 1, wherein the switch tray further comprises:
one conduits through which a liquid may flow to cool the switch tray during use.

5. The switch tray as in claim 1, wherein each of the plurality of switch ASICs has a set of ports whereby a first half the set of ports is coupled to the internal connectors of the switch tray and a second half of the set of ports is coupled to the external connectors of the switch tray.

6. The switch tray as in claim 1, wherein the internal connectors are Ethernet connectors.

7. The switch tray as in claim 1, wherein the external connectors are Octal Small Form-factor Pluggable-Extended Density (OSFP-XP) connectors.

8. The switch tray as in claim 1, wherein the plurality of switch ASICs form communication planes between the processors located within the fabric rack.

9. The switch tray as in claim 8, wherein each of the communication planes connects ports of two or more of the processors located within the fabric rack.

10. The switch tray as in claim 8, wherein the communication planes are further connected to spine switches external to the fabric rack that convey the inter-rack traffic between the processors located within the fabric rack and the external processors located in the one or more external fabric racks.

11. A fabric rack comprising:
a cable backplane;
internal processors communicatively coupled to the cable backplane; and
one or more switch trays, each switch tray having:
internal connectors configured to communicatively couple the switch tray to the internal processors via the cable backplane;
a plurality of switch application-specific integrated circuits (ASICs) coupled to the internal connectors and configured to switch intra-rack traffic between the internal processors located within the fabric rack; and
external connectors coupled to the plurality of switch ASICs, wherein the plurality of switch ASICs are further configured to switch inter-rack traffic between the internal processors located within the fabric rack and external processors located in one or more external fabric racks.

12. The fabric rack as in claim 11, wherein the internal processors located within the fabric rack are graphics processing units (GPUs).

13. The fabric rack as in claim 11, wherein the fabric rack comprises:
one or more compute trays that are coupled to the cable backplane and house the internal processors located within the fabric rack.

14. The fabric rack as in claim 11, wherein the one or more switch trays each comprises:
one conduits through which a liquid may flow to cool that switch tray during use.

15. The fabric rack as in claim 11, wherein each of the plurality of switch ASICs has a set of ports whereby a first half the set of ports is coupled to the internal connectors of their switch tray and a second half of the set of ports is coupled to the external connectors of their switch tray.

16. The fabric rack as in claim 11, wherein the internal connectors are Ethernet connectors.

17. The fabric rack as in claim 11, wherein the external connectors are Octal Small Form-factor Pluggable-Extended Density (OSFP-XP) connectors.

18. The fabric rack as in claim 11, wherein the plurality of switch ASICs form communication planes between the internal processors located within the fabric rack.

19. The fabric rack as in claim 18, wherein the communication planes are further connected to spine switches external to the fabric rack that convey the inter-rack traffic between the internal processors located within the fabric rack and the external processors located in the one or more external fabric racks.

20. A method comprising:
receiving, at a switch application-specific integrated circuit (ASIC) of a switch tray in a fabric rack, an intra-rack communication from a first processor located within the fabric rack and destined for a second processor located within the fabric rack;
sending, by the switch ASIC of the switch tray, the intra-rack communication to the second processor located within the fabric rack;
receiving, at the switch ASIC of the switch tray, an inter-rack communication from the first processor and destined for an external processor located external to the fabric rack; and
sending, by the switch ASIC of the switch tray, the inter-rack communication via an external connector of the switch tray towards the external processor.
